(19) United States
(12) Patent Application Publication
(10) Pub. No.: US 2023/0276637 A1
(43) Pub. Date: Aug. 31, 2023

(54) SPIN ORBIT TORQUE MAGNETIC RANDOM ACCESS MEMORY CELL, MEMORY ARRAY, AND MEMORY

(71) Applicant: Institute of Microelectronics, Chinese Academy of Sciences, Beijing (CN)

(72) Inventors: Guozhong Xing, Beijing (CN); Huai Lin, Beijing (CN); Ming Liu, Beijing (CN)

(73) Assignee: Institute of Microelectronics, Chinese Academy of Sciences, Beijing (CN)

(21) Appl. No.: 18/003,038

(22) PCT Filed: Jun. 24, 2020
(86) PCT No.: PCT/CN2020/098167

§ 371 Date: Dec. 22, 2022

(51) Int. Cl. H10B 61/00; H10N 52/85

(52) U.S. Cl. CPC H10B 61/10; H10N 52/85

(57) ABSTRACT

Provided are a spin orbit torque magnetic random access memory cell, a memory array and a memory, wherein the spin orbit torque magnetic random access memory cell includes: a magnetic tunnel and a selector; the selector is a two-dimensional material based selector; the magnetic tunnel junction is arranged above or below the selector; the magnetic tunnel junction includes an antiferromagnetic layer and a free layer; the free layer is adjacent to the antiferromagnetic layer; when the selector is turned on, the memory cell is conducted, a current generates a spin current which is injected into the free layer, and a magnetization direction of the free layer is switched by the exchange bias effect between the free layer and the antiferromagnetic layer. A deterministic magnetization switching of SOT-MRAM memory cell under zero magnetic field at room temperature may be implemented without an external magnetic field by using the exchange bias effect and applying an optimized bias voltage of the magnetic tunnel junction, so as to achieve a purpose of data writing and implement SOT-MRAM memory cell with double terminal structure.

### CROSS-REFERENCE TO RELATED APPLICATION

This application is a Section 371 National Stage Application of International Application No. PCT/CN2020/098167, filed on Jun. 24, 2020, entitled “SPIN ORBIT TORQUE MAGNETIC RANDOM ACCESS MEMORY CELL, MEMORY ARRAY, AND MEMORY”, the content of which is hereby incorporated by reference in its entirety.

### TECHNICAL FIELD

The present disclosure belongs to a field of magnetic random access memory, relates to a spin orbit torque magnetic random access memory cell, a memory array and a memory, and in particular, to a three-dimensional integrated spin orbit torque magnetic random access memory cell that implements directional magnetization switching without an external field, a memory array, and a memory.

### BACKGROUND

An unprecedented demand for a computing power of data processing chip due to a rapid development of global informatization has not only brought a great challenge to an existing memory architecture, but also driven a continuous innovation of new storage technologies. A traditional silicon-based storage technology is approaching its limit, highlighting barriers in energy consumption, reading and writing speed, reliability and storage capacity, which has promoted a rapid development of various new types of memory in recent years. As one of the new types of memory, Magnetic Random Access Memory (MRAM) has advantages of high reading and writing speed, low power consumption, non-volatility, radiation resistance, and so on, which make it attract extensive attention and in-depth research in the field of information all over the world.

Increasing technical requirements of information processing for memory reading and writing speed, storage capacity, power consumption and reliability has promoted an iteration of MRAM research results. The first generation of MRAM uses a pulse current to generate an Oersted field as a way to drive a writing of information on a ferromagnetic layer. However, this method leads to huge power consumption and inevitable interference to adjacent memory cells, which is not conducive to a high-density integration of devices. Therefore, the first generation of MRAM technology has not been widely expanded in practical applications. As the second generation MRAM, Spin Transfer Torque MRAM (STT-MRAM) has better device performance. A core of STT-MRAM is a Magnetic Tunnel Junction (MTJ) with a “sandwich” structure, and its basic structure is composed of upper and lower electrodes, and a reference layer, a tunneling layer and a free layer for storing information between the electrodes. An ultra-thin MTJ implements information storage through an injection of spins, and has the same reading and writing speed as the traditional Static Random Access Memory (SRAM), while greatly reducing a size of the device and reduces power consumption, and has a necessary non-volatility characteristic for future memory devices. Therefore, in the process of its development, researchers also positioned the STT-MRAM on high-speed memory devices similar to the SRAM, and constantly carried out innovative research and development. However, a writing process of STT-MRAM information requires a large current to directly pass through the tunnel junction, which is not conducive to device stability and is accompanied by relatively high power consumption.

In view of shortcomings of STT-MRAM storage technology, a new generation of MRAM emerges as the times require. In 2012, Spin Orbit Torque Magnetic Random Access Memory (SOT-MRAM) technology was proposed. Although the core structure of SOT-MRAM is also MTJ, the SOT-MRAM has a completely different information writing method. By using spin orbit torque (SOT) effect to switch a magnetic free layer, information may be written without a large current passing through the tunnel junction, and the information may be read and written separately, which may greatly improve the device stability. Experiments show that the SOT has faster magnetization switching speed and lower switching critical current density than STT, which may contribute to a significant reduction in power consumption.

Although the spin orbit torque (SOT) is expected to solve bottlenecks of speed, energy consumption and barrier reliability faced by the spin transfer torque (STT), the SOT still has urgent problems to be solved. Firstly, when writing data, the SOT-MRAM requires an additional auxiliary in-plane static magnetic field, which is not conducive to the manufacture and miniaturization of the SOT-MRAM. Secondly, the traditional three-terminal SOT-MRAM occupies a larger area than the double-terminal STT-MRAM, which is not conducive to a further improvement of storage capacity. Therefore, how to implement the information storage and reading of the SOT-MRAM with high speed, high reliability and low power consumption without relying on a full electrical drive of an external magnetic field, and how to improve the storage capacity of the SOT-MRAM have become key issues to be solved urgently on the development road of integrated SOT-MRAM.

### SUMMARY

In view of the above, the present disclosure provides a spin orbit torque magnetic random access memory cell, a memory array, and a memory.

According to one aspect of the present disclosure, there is provided a spin orbit torque magnetic random access memory cell, wherein the spin orbit torque magnetic random access memory cell includes: a selector being a two-dimensional material-based selector; a magnetic tunnel junction arranged above or below the selector; the magnetic tunnel junction includes an antiferromagnetic layer and a free layer, and the free layer is adjacent to the antiferromagnetic layer; when the selector is turned on, the memory cell is turned on, a current generates a spin current which is injected into the free layer, and a magnetization direction of the free layer is switched by the exchange bias effect between the free layer and the antiferromagnetic layer.

In some embodiments of the present disclosure, the magnetic tunnel junction further includes: a tunneling layer and a reference layer, wherein the reference layer, the tunneling layer, the free layer and the antiferromagnetic layer are stacked sequentially; the selector is adjacent to the antiferromagnetic layer or the reference layer; or, the magnetic tunnel junction further includes: a ferromagnetic layer, a tunneling layer, and a reference layer, wherein the reference layer, the tunneling layer, the free layer, the antiferromagnetic layer and the ferromagnetic layer are stacked sequentially; the selector is adjacent to the ferromagnetic layer or the reference layer.

In some embodiments of the present disclosure, the spin orbit torque magnetic random access memory cell further includes: a word line and a bit line, wherein the selector and the magnetic tunnel junction are arranged between the word line and the bit line.

In some embodiments of the present disclosure, the selector includes: a stacking cell, wherein the stacking cell is a metal-two-dimensional semiconductor-metal structure including a two-dimensional semiconductor layer and metal layers respectively arranged on an upper surface and a lower surface of the two-dimensional semiconductor layer; wherein when the two-dimensional material-based selector is energized and conducted, the stacking cell comprises two Schottky diode structures connected in anti-parallel.

In some embodiments of the present disclosure, the selector includes: M stacking cells, where M≥2, wherein each stacking cell is a metal-two-dimensional semiconductor-metal structure comprising a two-dimensional semiconductor layer and metal layers respectively arranged on an upper surface and a lower surface of the two-dimensional semiconductor layer; wherein each stacking cell includes a metal-two-dimensional semiconductor interface forming an ohmic contact and a metal-two-dimensional semiconductor interface forming a Schottky contact; wherein, the M stacking cells are arranged in a first direction parallel to a plane on which the two-dimensional semiconductor layer is located, an insulation layer is arranged between side walls of two adjacent stacking cells in the M stacking cells, and when the two-dimensional material-based selector is energized and conducted, the M stacking cells comprise M Schottky diode structures connected in anti-parallel.

In some embodiments of the present disclosure, the reference layer has a magnetic polarization in or out of a film plane; the free layer has a magnetic polarization parallel or antiparallel to the reference layer.

In some embodiments of the present disclosure, a material of the selector is a two-dimensional van der Waals material selected from WS₂ or WSe₂; a turn-on voltage of the selector is −1 V or 1 V; a turn-on current density of the selector is 10 MA/cm²; a thickness of the selector ranges from 2 nm to 7 nm.

In some embodiments of the present disclosure, a material of the tunneling layer is one or more of MgO, Al₂O₃, MaAl₂O₄ and h-BN or one or more of two-dimensional van der Waals material h-BN; a material of the free layer is a two-dimensional ferromagnetic material selected from one or more of Fe₃GeTe₂, FeCo, CrCoPt, CoFeB, CoFe₂Al, Mn₃Ga or two-dimensional ferromagnetic materials Ni₃GeTe₂, VSe₂ and CrI₃; a material of the antiferromagnetic layer is selected from one or more of Fe₃GeTe₂, IrMn, FeMn, NiMn, CoMn, PtMn, Co/Pt, FeO, CoO, NiO and MnO; the antiferromagnetic layer is at least one layer; a material of the ferromagnetic layer is selected from one or more of Fe₃GeTe₂, IrMn, FeMn, NiMn, CoMn, PtMn, Co/Pt, FeO, CoO, NiO and MnO; the ferromagnetic layer is at least one layer.

In some embodiments of the present disclosure, a material of the word line is selected from one or more of Ta, Pt, and β-W.

According to another aspect of the present disclosure, there is provided a spin orbit torque magnetic random access memory array, wherein the memory array includes: at least one layer of cross memory array, wherein each layer of cross memory array includes: a bit line array including a plurality of bit lines arranged in parallel in a first direction; a word line array including a plurality of word lines arranged in parallel in a second direction, wherein an included angle is formed between the first direction and the second direction; and a plurality of memory cells arranged at intersections of the word line array and the bit line array, wherein each memory cell of the plurality of memory cells is the memory cell described above.

According to the embodiments of the present disclosure, the memory array further includes: a transistor, wherein the transistor is connected in series with each word line of the plurality of word lines in each layer of cross memory array and configured to control an on-off of the word line.

According to another aspect of the present disclosure, there is provided a spin orbit torque magnetic random access memory, including the spin orbit torque magnetic random access memory array described above.

### BRIEF DESCRIPTION OF THE DRAWINGS

FIG. 1 shows a schematic diagram of a memory cell according to the embodiments of the present disclosure.

FIG. 2a shows a schematic diagram of a band energy structure of the selector in FIG. 1.

FIG. 2b shows a schematic diagram of an analog volt-ampere characteristic curve of the selector in FIG. 1.

FIG. 3 shows a schematic structural diagram of a ferromagnetic material of a magnetic tunnel junction of a memory cell according to the embodiments of the present disclosure.

FIG. 4a shows a schematic diagram of a spin direction of a ferromagnetic material in a free layer of a memory cell being opposite to that of a reference layer according to the embodiments of the present disclosure.

FIG. 4b shows a schematic diagram of a spin direction of a ferromagnetic material in a free layer of a memory cell being the same as that of a reference layer according to the embodiments of the present disclosure.

FIG. 5 shows a three-dimensional structural diagram of a spin orbit torque magnetic random access memory according to the embodiments of the present disclosure.

### SYMBOL DESCRIPTION

11—bit line array;
110—bit line;
120—selector;
130—magnetic tunnel junction;
131—reference layer;
132—tunneling layer;
133—free layer;
134—antiferromagnetic layer;
14—word line array;
140—word line;
141—sub word line;
150—transistor;
200—memory array.

### DETAILED DESCRIPTION OF EMBODIMENTS

The present disclosure provides a spin orbit torque magnetic random access memory cell, a memory array and a memory, wherein the spin orbit torque magnetic random access memory cell includes: a magnetic tunnel junction and a selector; the selector is a two-dimensional material based selector; the magnetic tunnel junction is arranged above or below the selector; the magnetic tunnel junction includes an antiferromagnetic layer and a free layer; the free layer is adjacent to the antiferromagnetic layer; when the selector is turned on, the memory cell is conducted, a current generates a spin current which is injected into the free layer, and a magnetization direction of the free layer is switched by the exchange bias effect between the free layer and the antiferromagnetic layer. The present disclosure uses the exchange bias effect without an external field, and may implement a deterministic magnetization switching of SOT-MRAM memory cell under zero magnetic field at room temperature by applying MTJ optimized bias voltage, so as to achieve a purpose of data writing and implement a SOT-MRAM memory cell with double terminal structure.

The magnetic tunnel junction described above may be a tunnel junction including an antiferromagnetic layer. In a specific description of the embodiments, sometimes the conventional magnetic tunnel junction (MTJ) including a free layer, a tunneling layer and a reference layer will be described as a whole, and the antiferromagnetic layer will be described separately.

In order to make the objectives, technical solutions and advantages of the present disclosure more apparent, the present disclosure will be described in further detail below with reference to specific embodiments and the accompanying drawings.

Some embodiments of the present disclosure will be described more comprehensively later with reference to the accompanying drawings, and some but not all of the embodiments will be shown. In fact, various embodiments of the present disclosure may be implemented in many different forms and should not be interpreted as being limited to the embodiments set forth herein; in contrast, these embodiments are provided such that the present disclosure meets applicable legal requirements.

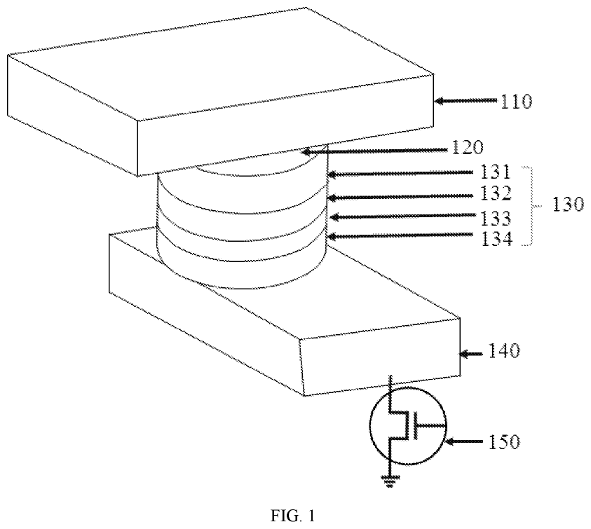

In the first exemplary embodiment of the present disclosure, there is provided a spin orbit torque magnetic random access memory cell. FIG. 1 shows a schematic diagram of a memory cell according to the embodiments of the present disclosure. As shown in FIG. 1, the spin orbit torque magnetic random access memory cell of this embodiment includes a word line 140, a bit line 110, a magnetic tunnel junction 130 and a selector 120. The selector 120 and the magnetic tunnel junction 130 are arranged between the word line 140 and the bit line 110. The selector 120 is a two-dimensional material-based selector. The magnetic tunnel junction 130 is arranged above or below the selector 120. The magnetic tunnel junction 130 includes an antiferromagnetic layer 134 and a free layer 133, and the free layer 133 is adjacent to the antiferromagnetic layer 134. The selector 120 is turned on, the memory cell is conducted, a current generates a spin current which is injected into the free layer 133, and a magnetization direction of the free layer 133 is switched by the exchange bias effect between the free layer 133 and the antiferromagnetic layer 134.

The spin orbit torque magnetic random access memory cell provided in this embodiment has a double terminal structure, wherein the bit line 110 is connected with the selector 120, the bit line 110 is made of metal, and the selector 120 is formed of two-dimensional material and metal heterojunction. The antiferromagnetic tunnel junction 130 of this embodiment includes: a reference layer 131, a tunneling layer 132, the free layer 133 and the antiferromagnetic layer 134. The reference layer 131, the tunneling layer 132, the free layer 133 and the antiferromagnetic layer 134 are stacked sequentially. The selector 120 is adjacent to the antiferromagnetic layer 134. It should be noted that the term “stacked sequentially” means that the layers are sequentially stacked in order, and other layers may be disposed between the layers, and the stacking order may be from bottom to top or from top to bottom. A bottom of the antiferromagnetic layer 134 is coupled with the word line 140. In this embodiment, a transistor 150 of the memory cell is a selection/gating transistor and the other end thereof is connected with a control terminal, which may complete a write control of the spin orbit torque magnetic random access memory cell.

Each component of the spin orbit torque magnetic random access memory cell of this embodiment will be described in detail below.

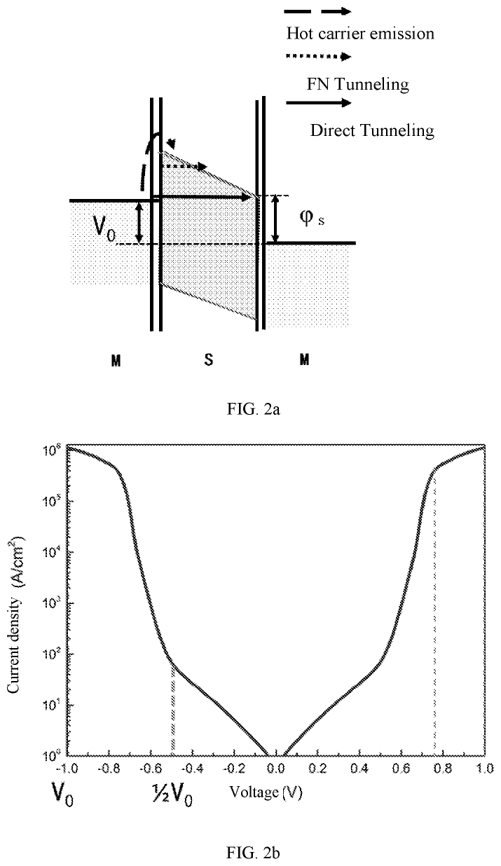

The selector 120 is composed of a metal-semiconductor-metal (MSM) structure in parallel, and a bias voltage is applied at both ends, as shown in FIG. 2A. When the applied bias voltage is small, one side of the Schottky barrier is conducted in a forward direction and the other side is cut off in a reverse direction. At this point, its volt ampere characteristic is shown in FIG. 2b, the voltage is less than ½Vo, the current is an extremely small and may be regarded as a cut-off state. When the applied bias voltage increases, a current density of hot carrier emission, FN tunneling and direct tunneling in the semiconductor increases, and when a threshold voltage Vo for turning on is reached, the selector is turned on, the spin orbit torque magnetic random access memory cell is conducted, and read and write operations can be carried out.

The components of the selector 120 will be described in detail below. In one embodiment, the selector includes: a stacking cell, wherein the stacking cell is a metal-two-dimensional semiconductor-metal structure including a two-dimensional semiconductor layer and metal layers respectively arranged on an upper surface and a lower surface of the two-dimensional semiconductor layer, wherein when the two-dimensional material-based selector is energized and conducted, the stacking cell includes two Schottky diode structures connected in anti-parallel.

In another embodiment, the selector includes: M stacking cells, where M≥2, wherein each stacking cell is a metal-two-dimensional semiconductor-metal structure including a two-dimensional semiconductor layer and metal layers respectively arranged on an upper surface and a lower surface of the two-dimensional semiconductor layer; wherein each stacking cell includes a metal-two-dimensional semiconductor interface forming an ohmic contact and a metal-two-dimensional semiconductor interface forming a Schottky contact; the M stacking cells are arranged in a first direction (x direction) parallel to a plane on which the two-dimensional semiconductor layer is located, an insulation layer is arranged between side walls of two adjacent stacking cells in the M stacking cells, and when the two-dimensional material-based selector is energized and conducted, the M stacking cells includes M Schottky diode structures connected in anti-parallel.

The selector described above may provide a driving current of a selected memory cell and ensure an extremely small leakage current of an unselected portion, and the two-dimensional material based selector has nano scalability, compatibility with COMS process, bidirectional threshold conduction characteristic, low turn-on voltage, high turn-on current density, low turn-on resistance, high nonlinearity and excellent thermal stability.

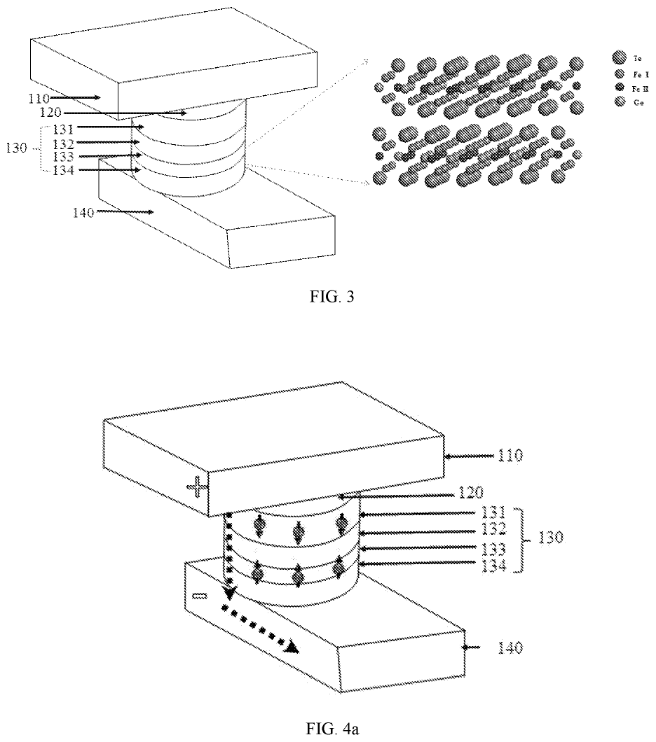

FIG. 3 shows a structural diagram of a ferromagnetic material of a magnetic tunnel junction of a memory cell according to an embodiment of the present disclosure. In this embodiment, a reference layer 131 and a free layer 133 include two-dimensional van der Waals ferromagnetic material Fe₃GeTe₂ (FGT), and its lattice structure diagram is shown in 130 in FIG. 3. The free layer 133 and the reference layer 131 are connected by van der Waals force, and the material itself is compatible with modern integrated circuit technology. A few layers or even single-layer two-dimensional material may be obtained by Chemical Vapor Deposition (CVD), Atomic Layer Deposition (ALD) and other technical methods. Its atomic layer surface is smooth without additional hanging bonds, and has more excellent interface characteristics, which may reduce a loss caused by scattering during data writing. Other optional materials include one or more of FeCo, CrCoPt, CoFeB, CoFe₂Al, Mn₃Ga or two-dimensional ferromagnetic materials Ni₃GeTe₂, VSe₂ and CrI₃. The material used for a tunneling layer 132 is MgO, and alternative materials include Al₂O₃, MaAl₂O₄ or one of two-dimensional van der Waals material h-BN. An antiferromagnetic layer 134 in this embodiment uses Fe₃GeTe₂ with antiferromagnetism. A ferromagnetic/antiferromagnetic phase in Fe₃GeTe₂ has an effective exchange bias magnetic field HEB, and by applying an optimized bias voltage of the magnetic tunnel junction 130, the deterministic magnetization switching of the spin orbit torque magnetic random access memory cell at room temperature without an external magnetic field can be implemented. The antiferromagnetic layer 134 may also be composed of other antiferromagnetic materials, including one or more layers of IrMn, FeMn, NiMn, CoMn, PtMn, and Co/Pt, or one or more layers of metal oxide antiferromagnetic materials FeO, CoO, NiO, and MnO. In the material Fe3GeTe2, a constant bias voltage of 1V to 2V may be applied on one side of the material Fe3GeTe2, and the voltage may induce electrons to fill subbands of dZ2, dxz and dyz orbits from Fe sequentially, resulting in an increase in an edge electronic state density, and then an increase of an environmental stability temperature in a long-range ordered magnetic moment structure, i.e., a significant increase of Curie temperature. For a ferromagnetic material with Curie temperature lower than room temperature or an antiferromagnetic material with N è el temperature lower than room temperature, it is also suitable to modulate the above material by applying a bias voltage, so as to ensure a controllable modulation of two-dimensional material ferromagnetism and antiferromagnetism through an optimization of bias voltage at room temperature.

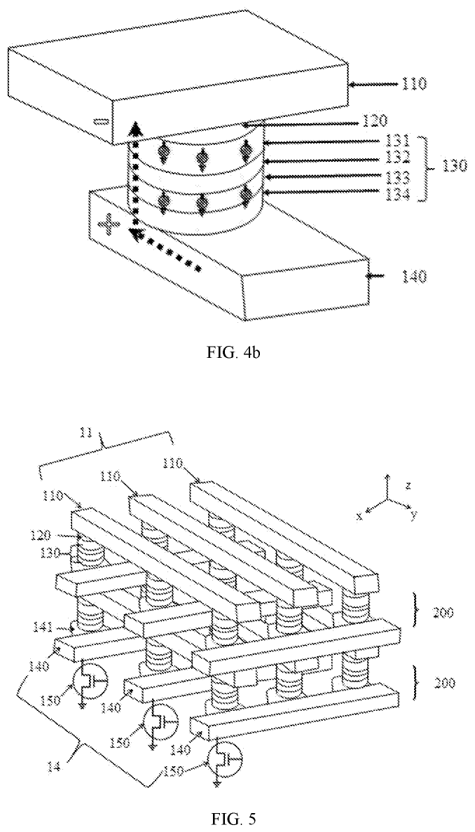

FIG. 4a shows a schematic diagram of a spin direction of a ferromagnetic material in a free layer of a memory cell being opposite to that of a reference layer according to the embodiments of the present disclosure. As shown in FIG. 4a, when the spin orbit torque magnetic random access memory cell performs a write operation, a bias voltage +V₁ (which is greater than the turn-on voltage of the selector) is applied between a bit line 110 and a word line 140, and at this point, a selector 120 is conducted and a current flow through the memory cell. A writing principle of the double terminal memory cell is dominated by SOT, and when the current flows through a heavy metal layer of the word line 140, the current generates a spin current which is injected into a combined structure of a free layer 133 and an antiferromagnetic layer 134. A material of the antiferromagnetic layer 134 is selected from one or more of Fe₃GeTe₂, IrMn, FeMn, NiMn, CoMn, PtMn, Co/Pt, FeO, CoO, NiO and MnO. At this point, the antiferromagnetic layer 134 may be coupled with the adjacent free layer 133, resulting in an exchange bias field in a plane direction, and this field may replace the external magnetic field required by the traditional SOT-MRAM, that is, provide an in-plane field, so as to break a broken-symmetry and implement the deterministic magnetization switching in the free layer ferromagnetic material. At this point, the spin direction of the ferromagnetic material in the free layer 133 is opposite to that of a reference layer 131, and a magnetic tunnel junction 130 presents a high resistance state, for example, representing data “1”. In another embodiment, the writing principle of the double terminal memory cell is dominated by SOT, and when the current flows through the heavy metal layer of the word line 140, the current generates a spin current which is injected into a combined structure of the free layer 133, the antiferromagnetic layer 134 and a ferromagnetic layer (not shown). A material of the ferromagnetic layer is selected from one or more of Fe₃GeTe₂, IrMn, FeMn, NiMn, CoMn, PtMn, Co/Pt, FeO, CoO, NiO and MnO. It should be noted that the materials involved in the present disclosure also include corresponding material systems implemented by component, surface and interface modulation or element doping.

As shown in FIG. 4b, when writing “0”, an applied voltage −V₁ is applied between a bit line 110 and a word line 140, and the current is reversed. As described above, at this point, the device sets the spin direction in a free layer 133 to the same direction as a reference layer 131 through the SOT effect and the exchange bias effect, and a magnetic tunnel junction 130 presents a low resistance state, for example, representing data “0”. Thus, a programming storage of binary numbers may be implemented.

Due to the exchange bias effect between the free layer and the antiferromagnetic layer of the magnetic tunnel junction, combined with the application of the optimized bias voltage of the magnetic tunnel junction, the information writing of SOT-MRAM at room temperature without an external magnetic field may be implemented, and the conversion efficiency of charge flow to spin current and the absorption of spin current by free layer magnetic materials may be increased.

The embodiments of the present disclosure further provide a spin orbit torque magnetic random access memory array. FIG. 5 shows a schematic diagram of a spin orbit torque magnetic random access memory according to the embodiments of the present disclosure. As shown in FIG. 5, the spin orbit torque magnetic random access memory of the present disclosure includes: at least one layer of cross memory array, and each layer of cross memory array includes: a bit line array 11, a word line array 14 and a memory cell. The bit line array 11 includes a plurality of bit lines 110 arranged in parallel in a first direction (x direction). The word line array 14 includes a plurality of word lines 140 arranged in parallel in a second direction (y direction); wherein an included angle is formed between the first direction and the second direction. The word line array 14 includes three word lines 140 and a transistor 150 connected in series at the end of the word lines 140. The transistor is connected in series with each word line 140 of the plurality of word lines of each layer of cross memory array and configured to control an on-off of the word line. As a common word line, each word line 140 is provided with a plurality of sub word lines 141 on the same side, which are configured to connect with the memory cell to avoid interference to memory cells on other word lines in the same layer cross memory array when writing data. As shown in FIG. 5, three bit lines 110 are arranged equidistant in a parallel array. In practical application, the number is not limited to three. The three word lines 140 are arranged equidistant in a parallel array, and the end of each word line 140 is connected in series with the transistor 150, which is the selection/gating transistor in this embodiment. In practical application, the number of word lines 140 is not limited to three. When the memory array is larger than one, a plurality of memory arrays are stacked vertically. The number of layers is not limited to two, and a plurality of layers may be superimposed until an electronic circuit resolution or process of the spin orbit torque magnetic random access memory reaches an upper limit of the number of layers.

By adopting the cross stack array, three-dimensional integration and large-scale production may be implemented, and the storage capacity may be greatly improved compared with the traditional two-dimensional memory array.

The embodiments of the present disclosure further provide a spin orbit torque magnetic random access memory, which includes the memory cell and/or the memory array described above.

According to the embodiments of the present disclosure, the spin orbit torque magnetic random access memory cell, the memory array and the memory described above have at least one or part of following beneficial effects.

(1) In the present disclosure, the exchange bias effect of the free layer and the antiferromagnetic layer in the magnetic tunnel junction combined with an application of an optimized bias voltage of the magnetic tunnel junction may implement an information writing of SOT-MRAM at room temperature without an external magnetic field, and increase a conversion efficiency of charge flow to spin flow and an absorption of spin flow by the free layer magnetic material. The magnetic tunnel junction provided in the present disclosure has advantages of high speed, high reliability, small size and low power consumption.

(2) The gate provided in the present disclosure may provide a driving current of a selected memory cell and ensure an extremely small leakage current of an unselected portion, and the two-dimensional material based gate has nano scalability, compatibility with COMS process, bidirectional threshold conduction characteristic, low turn-on voltage, high turn-on current density, low turn-on resistance, high nonlinearity and excellent thermal stability.

(3) In the present disclosure, the cross stack array is adopted to achieve three-dimensional integration and large-scale production. Compared with the traditional two-dimensional memory array, the storage capacity may be greatly improved.

So far, the embodiments of the present disclosure have been described in detail in combination with the drawings. It should be noted that the implementations not shown or described in the drawings or the text of the description are of forms known to those of ordinary skill in the art and are not described in detail. In addition, the definitions of each element and method described above are not limited to various specific structures, shapes or modes mentioned in the embodiments, and those of ordinary skill in the art may make simple modifications or substitutions, for example:

(1) The shapes of the selector, the magnetic tunnel junction and the antiferromagnetic layer may be replaced by a simple shape such as a rectangle and a ring.

(2) The two-dimensional selector may be located above or below the magnetic tunnel junction by a simple movement of the selector in a location of the memory cell in the array.

According to the above description, those skilled in the art should have a clear understanding of the spin orbit torque magnetic random access memory cell, the memory array and the memory of the present disclosure.

In summary, the present disclosure provides a three-dimensional integrated spin orbit torque magnetic random access memory cell that implements directional magnetization switching without an external field, a memory array and a memory, which has the advantages of high speed, high reliability, small size and low power consumption, and has a wide application prospect in the field of random access memory.

It should also be noted that directional terms mentioned in the embodiments, such as “upper”, “lower”, “front”, “rear”, “left”, “right”, etc., are only directions referring to the drawings, and are not intended to limit the protection scope of the present disclosure. Throughout the drawings, the same elements are represented by the same or similar reference signs. Conventional structures or configurations will be omitted when they may obscure the understanding of the present disclosure.

Moreover, the shape and size of each component in the drawings do not reflect the real size and proportion, but only illustrate the contents of the embodiments of the present disclosure. In addition, in the claims, any reference symbol in parentheses shall not be constructed as a limitation of the claims.

Unless otherwise indicated, the numerical parameters in the description and the attached claims are approximations that may vary depending upon the desired properties obtained through the contents of the present disclosure. Specifically, all numbers expressing quantities of ingredients, reaction conditions, and so forth used in the description and claims should be understood as being modified by the term “about” in all instances. In general, the meaning of the expression is meant to encompass variations of a specified number by ±10% in some embodiments, by ±5% in some embodiments, by ±1% in some embodiments, by ±0.5% in some embodiments.

Furthermore, the word “comprising” does not exclude the presence of elements or steps not listed in the claims. The word “a” or “an” preceding an element does not exclude the presence of a plurality of such elements.

Similarly, it should be understood that in the foregoing description of exemplary embodiments of the present disclosure, various features of the present disclosure are sometimes grouped together in a single embodiment, figure, or description thereof for the purpose of simplifying the present disclosure and aiding in the understanding of one or more of the various disclosed aspects. However, the disclosed method should not be construed as reflecting the intention that the present disclosure sought to be protected contains more features than the features expressly recited in each claim. More specifically, as reflected in the appended claims, the disclosed aspects contain less than all features of the single embodiment disclosed above. Therefore, the claims following the specific embodiment are hereby expressly incorporated into the specific embodiment, with each claim standing on its own as a separate embodiment of the present disclosure.

The specific embodiments described above further detail the objectives, technical solutions and beneficial effects of the present disclosure. It should be understood that the above are only specific embodiments of the present disclosure, and are not intended to limit the scope of the present disclosure, and any modifications, equivalent substitutions, improvements and the like made within the spirit and principle of the present disclosure should all fall within the protection scope of the present disclosure.

What is claimed is:

1. A spin orbit torque magnetic random access memory cell, comprising:
a selector being a two-dimensional material-based selector;
a magnetic tunnel junction arranged above or below the selector, wherein the magnetic tunnel junction comprises an antiferromagnetic layer and a free layer, and the free layer is adjacent to the antiferromagnetic layer;
wherein when the selector is turned on, the memory cell is conducted, a current generates a spin current which is injected into the free layer, and a magnetization direction of the free layer is switched by the exchange bias effect between the free layer and the antiferromagnetic layer.

2. The spin orbit torque magnetic random access memory cell according to claim 1, wherein,
the magnetic tunnel junction further comprises a tunneling layer and a reference layer, wherein the reference layer, the tunneling layer, the free layer and the antiferromagnetic layer are stacked sequentially; the selector is adjacent to the antiferromagnetic layer or the reference layer; or,
the magnetic tunnel junction further comprises a ferromagnetic layer, a tunneling layer and a reference layer, wherein the reference layer, the tunneling layer, the free layer, the antiferromagnetic layer and the ferromagnetic layer are stacked sequentially; the selector is adjacent to the ferromagnetic layer or the reference layer.

3. The spin orbit torque magnetic random access memory cell according to claim 1, further comprising:
a word line and a bit line, wherein the selector and the magnetic tunnel junction are arranged between the word line and the bit line.

4. The spin orbit torque magnetic random access memory cell according to claim 1, wherein,
the selector comprises:
a stacking cell, wherein the stacking cell is a metal-two-dimensional semiconductor-metal structure comprising a two-dimensional semiconductor layer and metal layers respectively arranged on an upper surface and a lower surface of the two-dimensional semiconductor layer;
wherein when the two-dimensional material-based selector is energized and conducted, the stacking cell comprises two Schottky diode structures connected in anti-parallel; or,
the selector comprises:
M stacking cells, where M≥2, wherein each stacking cell is a metal-two-dimensional semiconductor-metal structure comprising a two-dimensional semiconductor layer and metal layers respectively arranged on an upper surface and a lower surface of the two-dimensional semiconductor layer;
wherein each stacking cell comprises a metal-two-dimensional semiconductor interface forming an ohmic contact and a metal-two-dimensional semiconductor interface forming a Schottky contact;
wherein the M stacking cells are arranged in a first direction parallel to a plane on which the two-dimensional semiconductor layer is located, an insulation layer is arranged between side walls of two adjacent stacking cells in the M stacking cells, and when the two-dimensional material-based selector is energized and conducted, the M stacking cells comprise M Schottky diode structures connected in anti-parallel.

5. The spin orbit torque magnetic random access memory cell according to claim 2, wherein the reference layer has a magnetization direction in or out of a plane; the free layer has a magnetization direction parallel or antiparallel to the reference layer.

6. The spin orbit torque magnetic random access memory cell according to claim 1, wherein a material of the selector is a two-dimensional van der Waals material selected from WS₂ or WSe₂; a turn-on voltage of the selector is −1 V or 1 V; a turn-on current density of the selector is 10 MA/cm²; a thickness of the selector ranges from 2 nm to 7 nm.

7. The spin orbit torque magnetic random access memory cell according to claim 2, wherein,
a material of the tunneling layer is one or more of MgO, Al₂O₃, MaAl₂O₄ and h-BN or one or more of two-dimensional van der Waals material h-BN; and/or,
a material of the free layer is a two-dimensional ferromagnetic material selected from one or more of Fe₃GeTe₂, FeCo, CrCoPt, CoFeB, CoFe₂Al, Mn₃Ga or two-dimensional ferromagnetic materials Ni₃GeTe₂, VSe₂ and CrI₃; and/or,
a material of the antiferromagnetic layer is selected from one or more of Fe₃GeTe₂, IrMn, FeMn, NiMn, CoMn, PtMn, Co/Pt, FeO, CoO, NiO and MnO; the antiferromagnetic layer is at least one layer; and/or,
a material of the ferromagnetic layer is selected from one or more of Fe₃GeTe₂, IrMn, FeMn, NiMn, CoMn, PtMn, Co/Pt, FeO, CoO, NiO and MnO; the ferromagnetic layer is at least one layer.

8. The spin orbit torque magnetic random access memory cell according to claim 3, wherein a material of the word line is selected from any one or more of Ta, Pt, and β-W.

9. A spin orbit torque magnetic random access memory array, wherein the memory array comprises:
at least one layer of cross memory array, wherein each layer of cross memory array comprises:
a bit line array comprising a plurality of bit lines arranged in parallel in a first direction;
a word line array comprising a plurality of word lines arranged in parallel in a second direction; wherein an included angle is formed between the first direction and the second direction; and
a plurality of memory cells arranged at intersections of the word line array and the bit line array, wherein each memory cell of the plurality of memory cells is the spin orbit torque magnetic random access memory cell according to any one of claims 1 to 8.

10. The spin orbit torque magnetic random access memory array according to claim 9, further comprising a transistor, wherein the transistor is connected in series with each word line of the plurality of word lines in each layer of cross memory array and configured to control an on-off of the word line.

11. A spin orbit torque magnetic random access memory, comprising the spin orbit torque magnetic random access memory array according to claim 9 or 10.
